(19) United States
(12) Patent Application Publication
(10) Pub. No.: US 2014/0132314 A1
(43) Pub. Date: May 15, 2014

(54) TRIANGULAR WAVEFORM GENERATING APPARATUS

(71) Applicant: SAMSUNG ELECTRO-MECHANICS CO., LTD., Suwon (KR)

(72) Inventor: Joo Yul KO, Suwon (KR)

(73) Assignee: SAMSUNG ELECTRO-MECHANICS CO., LTD., Suwon (KR)

(21) Appl. No.: 13/770,807

(22) Filed: Feb. 19, 2013

(30) Foreign Application Priority Data
Nov. 13, 2012 (KR) 10-2012-0128000

(51) Int. Cl. H03K 4/06

(52) U.S. Cl. CPC H03K 4/06
USPC 327/140

(57) ABSTRACT

There is provided a triangular waveform generating apparatus. The triangular waveform generating apparatus includes: a capacitor connected between an output terminal and a ground; a charging/discharging unit including a plurality of current sources to charge the capacitor with currents generated from the plurality of current sources or discharge currents therefrom; and a control unit comparing a charge voltage of the capacitor with a plurality of preset reference voltages and controlling the charging/discharging unit to allow a quantity of current charged in or discharged from the capacitor to be different in each of a plurality of periods formed by the plurality of reference voltages.

### CROSS-REFERENCE TO RELATED APPLICATIONS

This application claims the priority of Korean Patent Application No. 10-2012-0128000 filed on Nov. 13, 2012, in the Korean Intellectual Property Office, the disclosure of which is incorporated herein by reference.

### BACKGROUND OF THE INVENTION

1. Field of the Invention

The present invention relates to a triangular waveform generating apparatus for generating a piecewise linear triangular waveform by controlling a plurality of charge currents for charging a capacitor and a plurality of discharge currents for discharging the capacitor by comparing a charge voltage of the capacitor with different voltage levels.

2. Description of the Related Art

A pulse width modulation (PWM) signal generator is an apparatus that converts analog input signals, such as a triangular waveform signal, a reference signal, and the like, into pulsed output signals, and the like. In general, the PWM signal generator has been used to control on or off switching operations of a switching device included in a power supply apparatus by controlling a duty of a PWM signal.

Generally, as a method for controlling a duty of a PWM signal, an analog method of amplifying a reference voltage generating a PWM signal by using an external resistor and an operational amplifier having a predetermined gain has been used. However, such a method requires external components such as a resistor, and the like, to increase manufacturing costs, and uses the operational amplifier to increase an area of an integrated circuit.

Patent Document 1 in the following related art document relates to a multi-phase triangular waveform oscillation circuit and a switching regulator using the same and uses a plurality of constant current circuits to charge a capacitor, thereby generating triangular waveforms having the same frequency and peak value and having opposite phases.

However, Patent Document 1 does not disclose generating a triangular waveform having different slopes in each period, and it is different from the present invention in that a plurality of capacitors, rather than a single capacitor, are charged and discharged.

### RELATED ART DOCUMENT

(Patent Document 1) Japanese Patent Laid-Open Publication No. 2006-50310

### SUMMARY OF THE INVENTION

An aspect of the present invention provides a triangular waveform generating apparatus for generating a piecewise linear triangular waveform having different slopes in each period thereof so as to control a duty of a PWM signal without using external components such as a resistor, an operational amplifier, and the like.

According to an aspect of the present invention, there is provided a triangular waveform generating apparatus, including: a capacitor connected between an output terminal and a ground; a charging/discharging unit including a plurality of current sources to charge the capacitor with currents generated from the plurality of current sources or discharge currents therefrom; and a control unit comparing a charge voltage of the capacitor with a plurality of preset reference voltages and controlling the charging/discharging unit to allow a quantity of current charged in or discharged from the capacitor to be different in each of a plurality of periods formed by the plurality of reference voltages.

The control unit may control the charging/discharging unit to allow the quantity of current for charging the capacitor and the quantity of current for discharging the capacitor to be equal in any one of the plurality of periods.

The charging/discharging unit may include: a plurality of charge current sources generating charge current for charging the capacitor; a plurality of charge switches provided between the charge current sources and the capacitor to transfer the charge current to the capacitor or block the transferring of the charge current; a plurality of discharge current sources generating discharge current for discharging the capacitor; and a plurality of discharge switches provided between the discharge current sources and the capacitor to maintain or block the discharging of the charge voltage of the capacitor through the discharge current.

The quantity of charge current generated from one of the plurality of charge current sources may be equal to the quantity of discharge current generated from one of the plurality of discharge current sources.

Each of the plurality of charge current sources may generate the same quantity of charge current, and each of the plurality of discharge current sources may generate the same quantity of discharge current.

The plurality of charge current sources may generate different quantities of charge current, and the plurality of discharge current sources may generate different quantities of discharge current.

The control unit may compare the voltage of the capacitor with the plurality of reference voltages to control a switching operation of the plurality of charge switches and the plurality of discharge switches.

The control unit may include: a comparison unit including a plurality of comparators comparing the voltage of the capacitor with the plurality of reference voltages; and a state machine controlling a switching operation of at least one of the plurality of charge switches and the plurality of discharge switches according to comparison results output from the plurality of comparators.

The plurality of reference voltages may have different voltage levels.

According to another aspect of the present invention, there is provided a triangular waveform generating apparatus, including: a capacitor connected between an output terminal and a ground; a charging unit including a plurality of charge current sources to charge the capacitor; a discharging unit including a plurality of discharge current sources to discharge the capacitor; and a control unit comparing a charge voltage of the capacitor with a plurality of preset reference voltages and controlling the charging unit and the discharging unit to allow a slope of a triangular waveform output from the output terminal to be different in each of a plurality of periods formed by the plurality of reference voltages.

The control unit may control the charging unit and the discharging unit such that a positive slope of the triangular waveform and a negative slope of the triangular wave may have the same magnitude in any one of the plurality of periods.

The charging unit may include: the plurality of charge current sources generating charge current for charging the capacitor; and a plurality of charge switches provided between the plurality of charge current sources and the capacitor, respectively, to transfer the charge current to the capacitor or block the transferring of the charge current.

The discharging unit may include: the plurality of discharge current sources generating discharge current for discharging the capacitor; and a plurality of discharge switches provided between the plurality of discharge current sources and the capacitor, respectively, to maintain or block the discharging of the charge voltage of the capacitor through the discharge current.

The quantity of charge current generated from one of the plurality of charge current sources may be equal to the quantity of discharge current generated from one of the plurality of discharge current sources.

Each of the plurality of charge current sources may generate the same quantity of charge current, and each of the plurality of discharge current sources may generate the same quantity of discharge current.

The plurality of charge current sources may generate different quantities of charge current, and the plurality of discharge current sources may generate different quantities of discharge current.

The control unit may compare the voltage of the capacitor with the plurality of reference voltages to control a switching operation of the plurality of charge switches and the plurality of discharge switches.

The control unit may include: a comparison unit including a plurality of comparators comparing the voltage of the capacitor with the plurality of reference voltages; and a state machine controlling a switching operation of at least one of the plurality of charge switches and the plurality of discharge switches according to comparison results output from the plurality of comparators.

The plurality of reference voltages may have different voltage levels.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a circuit diagram illustrating an example of a general frequency generating apparatus;

FIGS. 2A and 2B are a graph illustrating a triangular waveform generated by the frequency generating apparatus of FIG. 1;

FIG. 3 is a circuit diagram illustrating a triangular waveform generating apparatus according to an embodiment of the present invention; and

FIG. 4 is a graph illustrating a charge voltage of a capacitor that is output from an output terminal of the triangular waveform generating apparatus according to the embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

Throughout the drawings, the same reference numerals will be used to designate the same or like components.

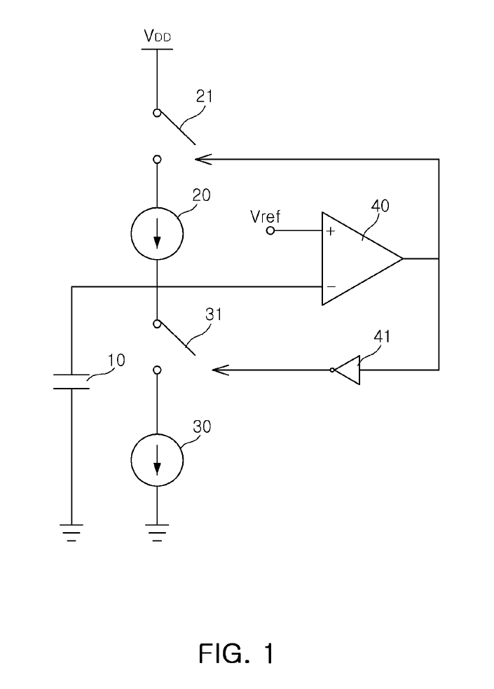

FIG. 1 is a circuit diagram illustrating a general frequency generating apparatus. Referring to FIG. 1, a frequency generating apparatus may include a capacitor 10, a charge current source 20 for charging the capacitor 10, a first switch 21 for cutting-off a flow of current generated from the charge current source 20, a discharge current source 30 for discharging charge voltage of the capacitor 10, a second switch 31 for cutting-off a flow of current generated from the discharge current source 30, a comparator 40 for comparing the charge voltage of the capacitor 10 with a reference voltage Vref to generate a high/low signal, and an inverter 41 for inverting the high/low signal generated from the comparator 40.

Hereinafter, an operation of the frequency generating apparatus of FIG. 1 will be described under the assumption that there is no charge charged in the capacitor 10 at an early stage, that is, there is no charge voltage of the capacitor 10.

The comparator 40 has a non-inverting terminal receiving the reference voltage Vref applied thereto and an inverting terminal receiving the charge voltage of the capacitor 10 applied thereto. The reference voltage Vref may be set to be lower than a maximum charge voltage of the capacitor 10.

Since there is no charge charged in the capacitor 10 at an early stage, the comparator may output a high signal. The first switch 21 is turned on by the high signal, and the second switch 31 receiving a low signal obtained by inverting the high signal by the inverter 41 is turned off.

The current generated from the charge current source 20 by the turned on first switch 21 flows in the capacitor 10, and the capacitor 10 may be charged by the current output from the charge current source 20. In this case, a charging rate is determined by a quantity of current output from the charge current source 20. When the quantity of current generated from the charge current source 20 is increased, the voltage of the capacitor 10 has a steep positive slope, and when the quantity of current generated from the charge current source 20 is reduced, the voltage of the capacitor 10 has a gentle positive slope.

In the case in which the capacitor 10 is charged by the current output from the charge current source 20 and the charge voltage of the capacitor 10 is higher than the reference voltage Vref of the comparator 40, the comparator 40 may output a low signal. The first switch 21 is turned off by the low signal, and the second switch 31 receiving a high signal obtained by inverting the low signal by the inverter 41 is turned on.

The capacitor 10 may be discharged by the current generated from the discharge current source 30 by the turned on second switch 31. In this case, a discharging rate is determined by a quantity of current generated from the discharge current source 30.

When the quantity of current generated from the discharge current source 30 is increased, the voltage of the capacitor 10 has a steep negative slope, and when the quantity of current generated from the discharge current source 30 is reduced, the voltage of the capacitor 10 has a gentle negative slope.

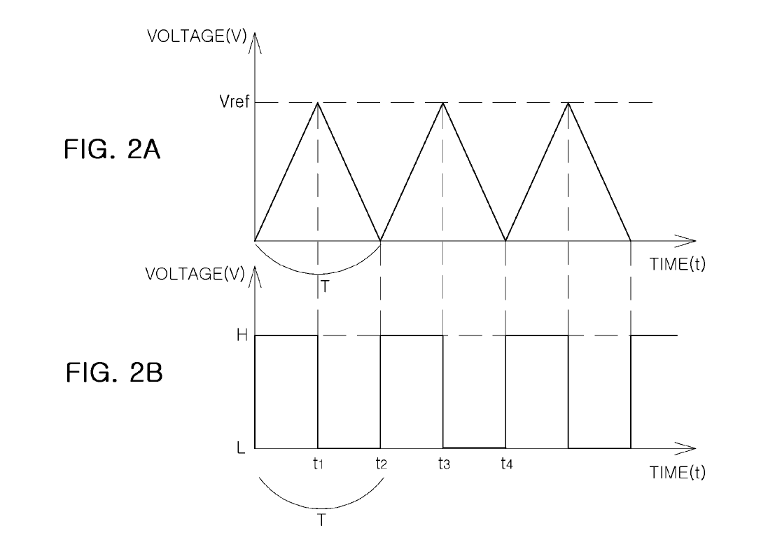

FIG. 2 is a graph illustrating a triangular waveform generated by the frequency generating apparatus of FIG. 1. An operation of the frequency generating apparatus of FIG. 1 will be described in more detail with reference to FIG. 2.

FIG. 2A is a graph illustrating the charge voltage of the capacitor 10 and is a graph illustrating a triangular waveform generated by the frequency generating apparatus, and FIG. 2B is a graph illustrating an output signal of the comparator 40.

For the triangular waveform generation of FIG. 2A, it may be assumed that the currents generated from the charge current source 20 and the discharge current source 30 of FIG. 1 have the same quantity of current.

As described above, since there is no charge charged in the capacitor 10 at an early stage, the comparator 40 may output a high signal. The first switch 21 is turned on by receiving the high signal applied thereto, such that the capacitor 10 is charged with charges generated from the charge current source 10, thereby increasing the charge voltage of the capacitor 10.

In the case of time t1 in which the charge voltage of the capacitor 10 is higher than the reference voltage Vref due to a gradual increase in the charge voltage of the capacitor 10, the comparator 40 may output a low signal.

Although not illustrated in FIG. 1, an output terminal of the comparator 40 is provided with a delay unit, such that the low signal transmitted from the comparator 40 may be transferred to the first switch 21 and the inverter 41. The delay unit may detect a falling timing of the output signal of the comparator 40 to maintain and output the low signal for a predetermined time t1 through t2.

When the low signal is output by the delay unit for the predetermined time t1 through t2, the first switch 21 is turned off and the second switch 31 receiving the high signal obtained by inverting the low signal by the inverter 41 is turned on. The second switch 31 is turned on such that the charge voltage of the capacitor 10 is gradually reduced by the discharge current source 30.

The charge current source 20 and the discharge current source 30 of FIG. 1 generate the same quantity of current, such that it can be appreciated that a rising slope and a falling slope of voltage by the charges of the capacitor of FIG. 2 are the same. A triangular waveform having a constant period T may be generated by repeatedly performing the foregoing operation.

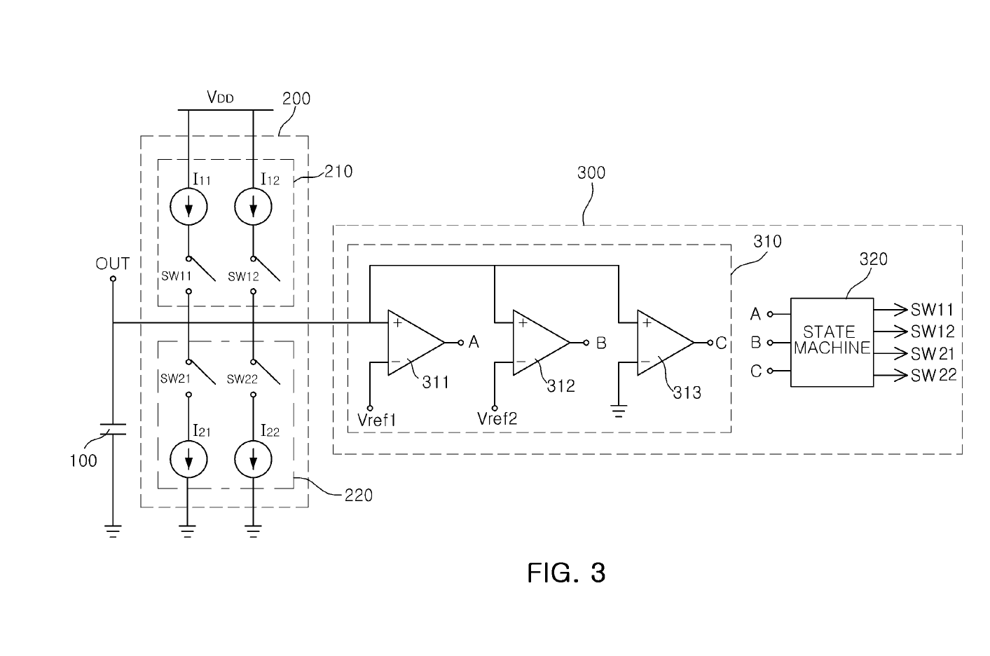

FIG. 3 is a circuit diagram illustrating a triangular waveform generating apparatus according to an embodiment of the present invention.

Referring to FIG. 3, the triangular waveform generating apparatus according to the embodiment of the present invention may include a capacitor 100, a charging/discharging unit 200, and a control unit 300.

The capacitor 100 is provided between an output terminal OUT and a ground, such that the triangular waveform generating apparatus may output a triangular waveform to the output terminal OUT by the charge voltage of the capacitor 100.

The charging/discharging unit 200 includes a plurality of current sources I11, I12, I21, and I22, such that the capacitor 100 may be charged or discharged by current output from the plurality of current sources I11, I12, I21, and I22. The charging/discharging unit 200 may include a charging unit 210 and a discharging unit 220.

The charging unit 210 may include the plurality of charge current sources I11 and I12 and a plurality of charge switches SW11 and SW12. The plurality of charge current sources I11 and I12 may be connected to a driving power supply VDD to generate current for charging the capacitor 100, and the plurality of charge switches SW11 and SW12 are provided between the plurality of charge current sources I11 and I12 and the capacitor 100, respectively, to transfer the current to the capacitor 100 or block the flow of the current transferred to the capacitor 100.

The discharging unit 220 may include the plurality of discharge current sources I21 and I22 and a plurality of discharge switches SW21 and SW22. The plurality of discharge current sources I21 and I22 may generate current for discharging the capacitor 100, and the plurality of discharge switches SW21 and SW22 are provided between the plurality of discharge current sources I21 and I22 and the capacitor 100, respectively, to discharge the charge voltage of the capacitor 100 to the ground or block the charge voltage of the capacitor 100 from being discharged due to the discharge current.

FIG. 3 illustrates that two charge current sources, two charge switches, two discharge current sources, and two discharge switches are provided, which is only schematically shown for convenience of explanation, and the present invention is not limited thereto. That is, the technical scope of the present invention encompasses matters easily derived by those skilled in the art and the charge current sources, the charge switches, the discharge current sources, and the discharge switches may be provided in plural.

The quantity of charge current generated from the plurality of charge current sources I11 and I12 may be set to be equal to each other. Alternatively, the quantity of charge current generated from the plurality of charge current sources I11 and I12 may be set to be different from each other.

Similar to the plurality of charge current sources I11 and I12, the quantity of discharge current generated from the plurality of discharge current sources I21 and I22 may be set to be equal to each other. Alternatively, the quantity of discharge current generated from the plurality of discharge current sources I21 and I22 may be set to be different from each other.

In this case, the quantity of charge current generated from one of the plurality of charge current sources I11 and I12 maybe equal to the quantity of discharge current generated from one of the plurality of discharge current sources I21 and I22. Described in detail, the plurality of charge current sources I11 and I12 and the plurality of discharge current sources I21 and I22 may be provided in the same number and the plurality of charge current sources I11 and I12 correspond to the plurality of discharge current sources I21 and I22 one to one, such that the one-to-one charge current source and discharge current source may generate the same quantity of current.

However, the present invention may include a different number of charge current sources and discharge current sources and the quantity of current generated from the plurality of charge current sources and the plurality of discharge current sources may be different from each other.

The control unit 300 may compare the charge voltage of the capacitor 100 with a plurality of preset reference voltages Vref1, Vref2, and ground voltage to control a switching operation of the plurality of charge switches SW11 and SW12 and the plurality of discharge switches SW21 and SW22. In detail, the control unit 300 may control the plurality of charge switches SW11 and SW12 and the plurality of discharge switches SW21 and SW22 so that the quantity of current for charging or discharging the capacitor 100 is different in each of a plurality of periods formed by the plurality of reference voltages Vref1, Vref2, and ground voltage.

That is, the slope of the triangular waveform output from the output terminal OUT may be different by making the quantity of current for charging or discharging the capacitor 100 different in each of the plurality of periods formed by the plurality of reference voltages Vref1, Vref2, and ground voltage.

The control unit 300 may control the charge switches and the discharge switches to allow the quantity of current for charging the capacitor 100 and the quantity of current for discharging the capacitor 100 to be the same in any one of the plurality of periods. In other words, the control unit 300 performs a control operation to allow the quantity of current for charging the capacitor 100 and the quantity of current for discharging the capacitor 100 to be equal, such that a positive slope and a negative slope of the triangular waveform output from the output terminal OUT may have the same magnitude.

The control unit 300 may include a comparison unit 310 including a plurality of comparators 311, 312, and 313 comparing the voltage of the capacitor 100 with the plurality of reference voltages Vref1, Vref2, and ground voltage, respectively, and a state machine 320 controlling the switching operation of at least one of the plurality of charge switches SW11 and SW12 and the plurality of discharge switches SW21 and SW22 according to the comparison results output from the comparison unit 310.

An output terminal A of the first comparator 311, an output terminal B of the second comparator 312, and an output terminal C of the third comparator 313 may be each connected to the state machine 320, and the output of the stage machine 320 may be applied to the plurality of charge switches SW11 and SW12 and the plurality of discharge switches SW21 and SW22, respectively, to control the switching operation of at least one switch. The state machine 320 determines a current output based on a previous input and a current input, which will be described below in detail.

The state machine 320 that is one component of the present invention maybe configured by a combination of a logic gate and a flip flop, and the technical scope of the present invention may encompass technical matters of performing functions and operations similar to the state machine 320.

Referring to FIG. 3, the comparator is illustrated as three comparators, that is, the first comparator 311, the second comparator 312, and the third comparator 313, which is only schematically shown for convenience of explanation, and the present invention is not limited thereto. That is, the technical scope of the present invention encompasses matters that can be easily changed in design by those skilled in the art and the comparator may be configured of a plurality of comparators.

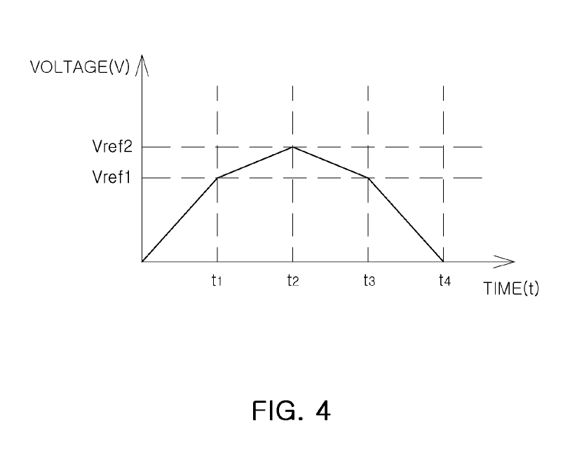

FIG. 4 is a graph illustrating the charge voltage of the capacitor 100 that is output from the output terminal of the triangular waveform generating apparatus according to the embodiment of the present invention. The operation of the triangular waveform generating apparatus of the present invention will be described with reference to FIGS. 3 and 4.

Non-inverting terminals of the first comparator 311, the second comparator 312, and the third comparator 313 are connected to the capacitor 100 such that the charge voltage of the capacitor 100 may be applied thereto. The first reference voltage Vref1 may be applied to an inverting terminal of the first comparator 311, the second reference voltage Vref2 may be applied to an inverting terminal of the second comparator 312, and the ground voltage may be applied to an inverting terminal of the third comparator 313. In this case, the first reference voltage Vref1 and the second reference voltage Vref2 refer to voltage, not the ground voltage, and it is assumed that the second reference voltage Vref2 is set to be higher than the first reference voltage Vref1.

TABLE 1

| | | | | Turned On |
|---|---|---|---|---|
| | A | B | C | Switch |
| Initial State | L | L | L | SW11 |
| Period 0 | L | L | H | SW11 |
| through t1 | | | | |
| Period t1 | H | L | H | SW12 |
| through t2 | | | | |
| Time t2 | H | H | H | SW21 |
| Period t2 | H | L | H | SW21 |
| through t3 | | | | |
| Period t3 | L | L | H | SW22 |
| through t4 | | | | |
| Time t4 | L | L | L | SW11 |

The above Table 1 is a truth table of the state machine 320. As described above, the state machine 320 determines the current output based on the previous input and the current input. However, when outputs of the output terminal A of the first comparator 311, the output terminal B of the second comparator 312, and the output terminal C of the third comparator 313 are all in a low level in the initial state, it is assumed that in the state machine 320, only the first charge switch SW11 is turned on.

Hereinafter, when the outputs of the output terminal A of the first comparator 311, the output terminal B of the second comparator 312, and the output terminal C of the third comparator 313 are X, Y, and Z, respectively, the input of the state machine 320 may be represented by X, Y, and Z.

Referring to the above Table 1, the state machine 320 may perform a control operation to turn on only the first charge switch SW11 at the time of changing the input state from (L, L, L) to (L, L, H) and turn off the remaining switches. In addition, the state machine 320 may perform a control operation to turn on only the second charge switch SW12 at the time of changing the input state from (L, L, H) to (H, L, H), turn on only the first discharge switch SW21 at the time of changing the input state from (H, L, H) to (H, H, H), turn on only the first discharge switch SW21 at the time of changing the input state from (H, H, H) to (H, L, H), turn on only the second discharge switch SW22 at the time of changing the input state from (H, L, H) to (L, L, H), and turn on only the first charge switch SW11 at the time of changing the input state from (L, L, H) to (L, L, L).

The truth table is an example, and two or more switches among the plurality of charge switches SW11 and SW12 and the plurality of discharge switches SW21 and SW22 may be controlled to be simultaneously turned on by the setting of the truth Table.

Period 0 through t1 of FIG. 4 will be described below. Described under the assumption that there is no charge in the capacitor 100 at the time of an initial charging of the capacitor, the voltage of the capacitor 100 is equal to the ground voltage and therefore, the output of the first comparator 311 has a low level, the output of the second comparator 312 has a low level, and the output of the third comparator 313 has a low level, such that the first charge switch SW11 may be turned on as the initial state of the state machine 320. The capacitor 100 is charged by the first charge current source I11 according to the turn on operation of the first charge switch SW11, such that the voltage of the capacitor 100 is increased, thereby changing the input state of the state machine 320 from (L, L, L) to (L, L, H). However, as illustrated in the above Table 1, the turn on operation of the first charge switch SW11 is maintained.

Referring to FIG. 4, the capacitor 100 is charged according to the charge current output from the first charge current source I11 by the turn on operation of the first charge switch SW11, such that the voltage of the capacitor 100 may be gradually increased. In this case, the slope of the charge voltage may be determined by the quantity of current generated from the first charge current source I11.

Period t1 through t2 of FIG. 4 will be described below. When the charge voltage of the capacitor 100 is gradually increased and thus, exceeds the first reference voltage Vref1, the output of the first comparator 311 has a high level, the output of the second comparator 312 has a low level, and the output of the third comparator 313 has a high level, such that the input state of the state machine 320 is changed from (L, L, H) to (H, L, H), thereby turning on the second charge switch SW12. In this case, the second charge switch SW12 is turned on, such that the capacitor 100 may be charged according to the charge current output from the second charge current source I12.

Describing period 0 to t1 and period t1 through t2 of FIG. 4, the slope of the charge voltage of the capacitor 100 in period 0 through t1 is steeper than in period t1 through t2, which means that the quantity of current generated per hour from the first charge current source I11 is larger than that generated per hour from the second charge current source I12.

However, this is only one example, and the quantity of current generated from the second charge current source I12 may be larger than that generated from the first charge current source I11.

Further, in the foregoing embodiment of the present invention, the first charge current source I11 and the second charge current source I12 generate the charge current having different quantities of current. However, the first charge current source I11 and the second charge current source I12 may generate the charge current having the same quantity of current. In this case, in order for the triangular waveform to have different slopes in each of the plurality of periods that are formed by the plurality of reference voltages Vref1, Vref2, and ground voltage, the number of switches that are turned on in each period may be controlled differently. For example, both of the first charge switch SW11 and the second charge switch SW12 may be controlled to be turned on in period 0 to t1, and any one of the first charge switch SW11 and the second charge switch SW12 may be controlled to be turned on in period t1 through t2.

Period t2 through t3 of FIG. 4 will be described below. When the charge voltage of the capacitor 100 is increased by the second charge current source I12 and thus, exceeds the second reference voltage Vref2, the input state of the state machine 320 is changed from (H, L, H) to (H, H, H), such that the first discharge switch SW21 is turned on.

Therefore, when the charge voltage of the capacitor 100 is discharged by the first discharge current source I21 and is thus equal to the second reference voltage Vref2, the input state of the state machine 320 is changed from (H, H, H) to (H, L, H). In this case, however, the turn on operation of the first discharge switch SW21 is maintained.

As shown in period t1 through t2 and period t2 through t3, the quantity of current generated from the second charge current source I12 and the quantity of current generated from the first discharge current source I21 are the same, such that the charge voltage of the capacitor 100 may have different signs but slopes having the same magnitude.

Period t3 through t4 of FIG. 4 will be described below. When the charge voltage of the capacitor 100 is reduced by the first discharge current source I21 and is thus equal to the first reference voltage Vref1, the input state of the state machine 320 is changed from (H, L, H) to (L, L, H), such that the second discharge switch SW22 is turned on. In this case, the capacitor 100 is discharged by the second discharge current source I22.

Comparing period 0 through t1 and period t3 through t4 of FIG. 4, similar to period t1 through t2 and period t2 through t3, it can be seen that the charge voltage of the capacitor 100 may have different signs but slopes having the same magnitude.

When the voltage of the capacitor 100 is gradually reduced and thus, falls to the ground voltage level, the input state of the state machine 320 is changed from (L, L, H) to (L, L, L), such that the first charge switch SW11 may be turned on again.

Thereafter, the foregoing process may be repeatedly performed.

As set forth above, according to embodiments of the present invention, a triangular waveform generating apparatus can generate a piecewise linear triangular waveform having different slopes in each of a plurality of periods so as to control a duty of a PWM signal, without using external components such as a resistor, an operational amplifier, and the like.

While the present invention has been shown and described in connection with the embodiments, it will be apparent to those skilled in the art that modifications and variations can be made without departing from the spirit and scope of the invention as defined by the appended claims.

What is claimed is:

1. A triangular waveform generating apparatus, comprising:
a capacitor connected between an output terminal and a ground;
a charging/discharging unit including a plurality of current sources to charge the capacitor with currents generated from the plurality of current sources or discharge currents therefrom; and
a control unit comparing a charge voltage of the capacitor with a plurality of preset reference voltages and controlling the charging/discharging unit to allow a quantity of current charged in or discharged from the capacitor to be different in each of a plurality of periods formed by the plurality of reference voltages.

2. The triangular waveform generating apparatus of claim 1, wherein the control unit controls the charging/discharging unit to allow the quantity of current for charging the capacitor and the quantity of current for discharging the capacitor to be equal in any one of the plurality of periods.

3. The apparatus of claim 1, wherein the charging/discharging unit includes:
a plurality of charge current sources generating charge current for charging the capacitor;
a plurality of charge switches provided between the charge current sources and the capacitor to transfer the charge current to the capacitor or block the transferring of the charge current;
a plurality of discharge current sources generating discharge current for discharging the capacitor; and
a plurality of discharge switches provided between the discharge current sources and the capacitor to maintain or block the discharging of the charge voltage of the capacitor through the discharge current.

4. The triangular waveform generating apparatus of claim 3, wherein the quantity of charge current generated from one of the plurality of charge current sources is equal to the quantity of discharge current generated from one of the plurality of discharge current sources.

5. The triangular waveform generating apparatus of claim 4, wherein each of the plurality of charge current sources generates the same quantity of charge current, and each of the plurality of discharge current sources generates the same quantity of discharge current.

6. The triangular waveform generating apparatus of claim 4, wherein the plurality of charge current sources generate different quantities of charge current, and the plurality of discharge current sources generate different quantities of discharge current.

7. The triangular waveform generating apparatus of claim 3, wherein the control unit compares the voltage of the capacitor with the plurality of reference voltages to control a switching operation of the plurality of charge switches and the plurality of discharge switches.

8. The triangular waveform generating apparatus of claim 3, wherein the control unit includes:
a comparison unit including a plurality of comparators comparing the voltage of the capacitor with the plurality of reference voltages; and
a state machine controlling a switching operation of at least one of the plurality of charge switches and the plurality of discharge switches according to comparison results output from the plurality of comparators.

9. The triangular waveform generating apparatus of claim 1, wherein the plurality of reference voltages have different voltage levels.

10. A triangular waveform generating apparatus, comprising:
a capacitor connected between an output terminal and a ground;
a charging unit including a plurality of charge current sources to charge the capacitor;
a discharging unit including a plurality of discharge current sources to discharge the capacitor; and
a control unit comparing a charge voltage of the capacitor with a plurality of preset reference voltages and controlling the charging unit and the discharging unit to allow a slope of a triangular waveform output from the output terminal to be different in each of a plurality of periods formed by the plurality of reference voltages.

11. The triangular waveform generating apparatus of claim 10, wherein the control unit controls the charging unit and the discharging unit such that a positive slope of the triangular waveform and a negative slope of the triangular wave have the same magnitude in any one of the plurality of periods.

12. The triangular waveform generating apparatus of claim 10, wherein the charging unit includes:
the plurality of charge current sources generating charge current for charging the capacitor; and
a plurality of charge switches provided between the plurality of charge current sources and the capacitor, respectively, to transfer the charge current to the capacitor or block the transferring of the charge current.

13. The triangular waveform generating apparatus of claim 12, wherein the discharging unit includes:
the plurality of discharge current sources generating discharge current for discharging the capacitor; and
a plurality of discharge switches provided between the plurality of discharge current sources and the capacitor, respectively, to maintain or block the discharging of the charge voltage of the capacitor through the discharge current.

14. The triangular waveform generating apparatus of claim 13, wherein the quantity of charge current generated from one of the plurality of charge current sources is equal to the quantity of discharge current generated from one of the plurality of discharge current sources.

15. The triangular waveform generating apparatus of claim 14, wherein each of the plurality of charge current sources generates the same quantity of charge current, and each of the plurality of discharge current sources generates the same quantity of discharge current.

16. The triangular waveform generating apparatus of claim 14, wherein the plurality of charge current sources generate different quantities of charge current, and the plurality of discharge current sources generate different quantities of discharge current.

17. The triangular waveform generating apparatus of claim 13, wherein the control unit compares the voltage of the capacitor with the plurality of reference voltages to control a switching operation of the plurality of charge switches and the plurality of discharge switches.

18. The triangular waveform generating apparatus of claim 13, wherein the control unit includes:
a comparison unit including a plurality of comparators comparing the voltage of the capacitor with the plurality of reference voltages; and
a state machine controlling a switching operation of at least one of the plurality of charge switches and the plurality of discharge switches according to comparison results output from the plurality of comparators.

19. The triangular waveform generating apparatus of claim 10, wherein the plurality of reference voltages have different voltage levels.
